(19) United States
(12) Patent Application Publication
(10) Pub. No.: US 2014/0247673 A1
(43) Pub. Date: Sep. 4, 2014

(54) ROW SHIFTING SHIFTABLE MEMORY

(71) Applicants: Naveen Muralimanohar, Santa Clara, CA (US); Hans Boehm, Palo Alto, CA (US)

(72) Inventors: Naveen Muralimanohar, Santa Clara, CA (US); Hans Boehm, Palo Alto, CA (US)

(21) Appl. No.: 14/349,401

(22) PCT Filed: Oct. 28, 2011
(86) PCT No.: PCT/US2011/058462

§ 371 Date: Apr. 3, 2014

(51) Int. Cl. G11C 11/4094; G11C 11/419

(52) U.S. Cl. CPC G11C 11/4094; G11C 11/419
USPC 365/189.02; 365/189.2

(57) ABSTRACT

A shiftable memory employs row shifting to shift data along a row. The shiftable memory includes memory cells arranged as a plurality of rows and a plurality of columns. The shiftable memory further includes shift logic to shift data from an output of a first column to an input of a second column. The shifted data is provided by a memory cell of the first column in a selected row. The shifted data is received and stored by a memory cell in the selected row of the second column. The shift logic facilitates shifting data along the selected row.

### CROSS-REFERENCE TO RELATED APPLICATIONS

N/A

### STATEMENT REGARDING FEDERALLY SPONSORED RESEARCH OR DEVELOPMENT

N/A

### BACKGROUND

Modern computers and related processing systems typically include a processor and some form of memory. The processor is generally responsible for performing the various computational tasks of the computer while the memory stores data that is used in and generated by the computational tasks. The architectural division of processing by the processor and data storage by the memory has proven successful for nearly the entire history of such systems.

For example, a typical general-purpose computer usually includes a central processing unit (CPU) and a main memory that communicate with one another over one or more communication channels (e.g., data, command and address buses). Typically, the CPU provides facilities to perform various arithmetic and logical operations, to provide operational sequencing and to otherwise control aspects of the general-purpose computer. For example, virtually all CPUs provide functions or operations for reading data from memory, writing data to memory, and executing programs comprising a set of instructions that utilizes the data to perform a predefined task. In addition, CPUs may handle input/output (I/O) allowing communication with peripherals as well as subsystems outside of the general-purpose computer. CPUs may even provide graphics processing to handle generating and updating a graphical display unit (e.g., a monitor), in some examples.

In contrast, the main memory of modern computers, which can include one or more of static random access memory (SRAM), dynamic random access memory (DRAM), read-only memory (ROM), programmable ROM (PROM), flash memory and a variety of other memory types, typically provides a relatively narrow set of capabilities. Principal among these capabilities is storing computer programs and data that are executed and used by the CPU. Among other limited capabilities that may be found in, or that are often associated with, the main memory of modern computers are certain memory management functions. For example, DRAM memory subsystems of main memory may possess circuitry for automatic refresh of data stored therein.

### BRIEF DESCRIPTION OF THE DRAWINGS

Various features of examples in accordance with the principles described herein may be more readily understood with reference to the following detailed description taken in conjunction with the accompanying drawings, where like reference numerals designate like structural elements, and in which:

FIG. 1A illustrates an example of a right shift of a contiguous subset of data stored in a horizontal row within a shiftable memory, according to an example of the principles described herein.

FIG. 1B illustrates an example of a left shift of a contiguous subset of data stored in a row within a shiftable memory, according to an example of the principles described herein.

FIG. 2 illustrates a block diagram of a shiftable memory that employs row shifting, according to an example in accordance with the principles described herein.

FIG. 3A illustrates a schematic diagram of an example SRAM memory cell, according to an example in accordance with the principles described herein.

FIG. 3B illustrates a schematic diagram of an example DRAM memory cell, according to an example in accordance with the principles described herein.

FIG. 4A illustrates a schematic diagram of shift logic comprising a multiplexer, according to an example in accordance with the principles described herein.

FIG. 4B illustrates a schematic diagram of shift logic comprising a multiplexer, according to another example in accordance with the principles described herein.

FIG. 5A illustrates a schematic block diagram of an example of word-sized shifting in the shiftable memory, according to an example in accordance with the principles described herein.

FIG. 5B illustrates a schematic block diagram of an example of word-sized shifting in the shiftable memory, according to another example in accordance with the principles described herein.

FIG. 5C illustrates a schematic block diagram of an example of shifting in the shiftable memory that employs remapping to dynamically control a shift distance, according to another example in accordance with the principles described herein.

FIG. 6 illustrates a flow chart of a method of shifting data in a shiftable memory, according to an example in accordance with the principles described herein.

Certain examples have other features that are one of in addition to and in lieu of the features illustrated in the above-referenced figures. These and other features are detailed below with reference to the above-referenced figures.

### DETAILED DESCRIPTION

Examples in accordance with the principles described herein provide a shiftable memory with built-in shifting capability that employs row shifting. In particular, a contiguous subset of data stored in a selected row of the shiftable memory is shifted by the shiftable memory to implement a built-in shifting capability. The built-in data shifting capability provides a lateral translation of the contiguous subset of data along the selected row. The lateral translation provides one or both of a right shift and a left shift of the stored data, according to various examples. Moreover, a direction of the shift (i,e., right or left) as well as an amount or distance of the shift may be selectable, for example. Examples in accordance with the principles described herein have application in computer systems and related data processing systems. In particular, the examples described herein provide shiftable memory with built-in shifting capability that is useful for a wide variety of data processing tasks.

According to various examples, the contiguous subset of stored data (e.g., data words) may be shifted within the memory from a first memory location to a second memory location along the row. The shifted data retain an ordered relationship within the contiguous subset when shifted to the second location the row, according to some examples. Moreover, the shift takes place entirely within the memory (e.g., within a memory chip or chip set) and the shift is generally accomplished without using resources, such as a processor, that are outside of the memory. In particular, the shift is accomplished using shift logic that comprises circuitry (e.g., a shift circuit) of the shiftable memory, according to various examples. Further, the shift does not involve data being moved between a processor and the memory, according to various examples. As a result, the memory with built-in shifting capability is referred to as ‘shiftable memory’ herein.

In some examples, the shift provided by the shiftable memory herein may be employed to ‘open’ a location in memory into which a new data may be inserted. In particular, a memory location either to the left or to the right of the contiguous subset of stored data may be rendered available for data insertion when the contiguous subset of stored data is moved by the shift within the shiftable memory. In some examples, the contiguous subset comprises data of an entire row (e.g., the selected row). In these examples, the memory location opened by the shift may be at one of a left end (e.g., a beginning) of the row and a right end (e.g., a terminal end) of the row. In other examples, the contiguous subset comprises only a portion of the data of the row. In such examples, the location opened by the shift may be located between the beginning and the terminal end of the row.

According to other examples, the shift may be used to delete or ‘overwrite’ data stored one of before a beginning of the contiguous subset and after an end of the contiguous subset. In particular, the data stored to the left or to the right the contiguous subset in a row may be overwritten with a portion of the contiguous subset itself, when the contiguous data is shifted by the shiftable memory. In other examples, when the contiguous subset comprises data of the entire row, shifting the contiguous subset may substantially shift a portion of the data off the end of the row. Depending on a direction of the shift, the data may be shifted off of either the right end or the left end, for example. Data shifted off the end of the row may be substantially ‘lost’ or removed from the shiftable memory and thus be considered deleted, according to some examples. When the data is deleted by being shifted off the end of the row, data deletion may occur without overwriting other data, in some examples. In other examples, data shifted off the end of the row may be subsequently transferred to another row (e.g., may be added to the beginning of an adjacent row). Data shifted off an end of the row and transferred to another row may result in a deletion of data in the other row as a result of overwriting data in the other row, for example.

According to some examples, shifting data to either insert data or delete data in the shiftable memory may be accomplished in less time, and in some examples in considerably less time, than is generally possible without using shiftable memory. In fact, the shift may be accomplished in substantially constant time (e.g., a fixed number of clock cycles) using shiftable memory, according to some examples. For example, the shift may be accomplished in one clock cycle of the shiftable memory.

In contrast, conventional memory that relies on a processor, for example, to perform a shift generally requires an amount of time that is proportional to an amount of data being shifted. For example, shifting data in conventional memory typically involves the processor reading the data to be shifted and then writing the data back to memory in another location. Reading and writing may be performed by the processor on a word-by-word basis due to the structure and functionality of conventional memory, for example. Since each unit of data (e.g., a data word) in the data being shifted is first read from the conventional memory by the processor and then subsequently written back to the conventional memory, the time to shift the data is generally proportional to the amount or length of the data (e.g., number of data words) being shifted, for example. The larger the amount of data, the longer the shift operation will take.

Moreover, conventional memory relies on a resource (e.g., the processor) that is external to the conventional memory to perform the reading and writing when shifting the data. Since the resource performing the shift is external to the conventional memory, each of the data words involved in the word-by-word shift must pass between the external resource and the conventional memory through some form of data bus or similar communication channel. The data bus or similar communication channel may substantially limit a speed of the read and write operations and as a result, an overall speed of the shift. Hence, shifting large subsets of data can become prohibitively expensive in terms of the processing time due to one or both of the effects of data bus speed and the proportional time aspects of performing a shift using conventional memory.

In accordance with the principles described herein, shiftable memory has built-in shifting capability so that data is not read and then written by an external resource to perform a shift, for example. The contiguous subset of stored data is identified to the shiftable memory (e.g., using an address and a length) and the shiftable memory is instructed to shift the contiguous subset. The shift is then accomplished by and takes place entirely within the shiftable memory. Speed limitations associated with transferring data to and from an external resource are substantially eliminated by shiftable memory, according to examples of the principles described herein. Moreover, time for shifting may be substantially independent of the length of the contiguous subset, for example.

In particular, shifting within the shiftable memory may be implemented with circuitry of the shiftable memory itself, according to the principles described herein. As such, shifting using shiftable memory does not require sequentially reading and writing each data word of the contiguous subset. For example, shifting using shiftable memory may shift all of the data in the contiguous subset in a substantially simultaneous manner along a row. As such, the shiftable memory may implement shifting of the contiguous subset in a time that is substantially independent of the length of the contiguous subset.

As mentioned above, in some examples, the shiftable memory may perform the shift in substantially constant time, according to examples of the principles described. By ‘constant time’ it is meant that a substantially similar amount of time is required to shift the contiguous subset of stored data regardless of the length of the contiguous subset. For example, an arbitrary length contiguous subset may be shifted in a single clock cycle, according to some examples. In another example, a shorter contiguous subset may need only a single clock cycle while a longer contiguous subset may require two or more clock cycles. However, while the shiftable memory may use more time for longer subsets than relatively shorter subsets, the shift is still performed sufficiently quickly such that the shift can be viewed as occurring in substantially constant time since the time required is not strictly proportional to the contiguous subset length, according to some examples.

Herein, the term ‘memory’ refers to substantially any sort of memory that can receive and store data. The memory is generally consistent with memory that may be employed by a computer processor or in a computer system, for example. In particular, by definition herein, memory refers to any sort of memory that can be written to and read from during operation of the computer that employs the memory. For example, the memory may comprise random access memory (RAM). The random access memory may be static RAM (SRAM), for example. Other types of memory include, but are not limited to, dynamic random access memory (DRAM) and various memory architectures based on latches, flip-flops and other bi-stable constructs (e.g., memristors).

Also herein by definition, a memory may comprise a plurality of memory cells arranged as an array, according to some examples. For example, the memory cells may be arranged as a two dimensional (2-D) array. Higher order (e.g., three or more dimensions) arrays also may be employed. In some examples, a lower order array (e.g., a linear array) is defined on an array with a larger dimension (e.g., 2-D array). For example, the 2-D array may be arranged as a rectangular 2-D array of memory cells comprising rows and columns (i.e., linear arrays). A three dimensional (3-D) arrangement of memory cells may be realized using a plurality of adjacent 2-D arrays, according to some examples. In addition, arrays may be divided into sub-arrays. For example, a 2-D rectangular array may be divided into quadrants as four sub-arrays.

A memory cell is a circuit or a related construct that holds or stores data, as defined and employed herein. Further, by definition herein, memory cells may generally store one or more ‘bits’ of data. For example, the bit may be or represent a binary value (e.g., ‘0’ or ‘1’) and the memory cell may hold a single bit. In another example, the memory cell may hold a plurality of binary value bits. For example, a memory cell may hold 4, 8, 16, 32 or 64 binary bits. In particular, the memory cell may hold or store a complete data word comprising the plurality of bits, as defined herein. In yet another example, the memory cell may hold data in another form (e.g., a hexadecimal value, an analog value, etc.). In particular, memory cells, as defined herein, are not restricted to storing data in a binary format but may, in some examples, hold or store an arbitrary data construct. However, for discussion purposes herein, binary data and memory cells that hold a single data bit are generally employed throughout by way of example and not by way of limitation, unless otherwise stipulated.

As used herein, a ‘row’ is defined as a collection or grouping of memory cells arrange in a one-dimensional (1-D) array (e.g., a linear array). The 2-D array may comprise a plurality of rows arranged in a substantially parallel manner, for example. Further herein, a row comprising a grouping of memory cells may hold data (e.g., a plurality of data bits) that constitute one or more data words of a particular computer system. According to various examples, the memory cells of a row are physically adjacent to one another. For example, a first memory cell of a row may be located immediately next to a second memory cell of the row, and so on from the beginning (e.g., left end) of the row to the terminal end (e.g., right end) of the row. A row may comprise a relatively large number of memory cells. For example, a length of a row may be 1024 data bits, 2048 data bits, 4096 data bits, or more, in various practical implementations, according to examples in accordance with the principles described herein.

Memory cells are also often referred to as ‘memory locations” herein. Strictly speaking, a memory location is a memory cell(s) at a particular location within the memory, the location being designated or identified by an address. The memory cell is accessed using the address, for example. However, for simplicity of discussion herein, memory cells are generally referred to as having or being at an address. Addresses or locations may be associated with a shiftable unit (e.g., a data word or set of data words) of the shiftable memory, for example. As such ‘location’ and address may be employed interchangeably herein. In addition ‘location” may be used to refer to a location of a contiguous subset of data that is designated by a starting address and an ending address, according to some examples. In other examples, the location of the contiguous subset may be designated by a starting (or an ending) address and a length of the contiguous subset. In yet other examples, the contiguous subset comprises substantially all of the data in a row. Hence, the contiguous subset may be designated by the row (e.g., an address of a first memory cell of the row) without resorting to pair of addresses or an address and a length.

Further herein and as noted above, a shift as performed by shiftable memory is defined as a lateral translation of a contiguous subset of data stored within the shiftable memory, unless otherwise stipulated. In particular, by definition herein, a shift using shiftable memory constitutes the lateral translation (e.g., left or right along a row) of the stored data bits within the contiguous subset from a first location to a second location in the row within the shiftable memory. Furthermore, the shift, when applied to the contiguous subset of stored data, translates all of the stored data within the contiguous subset. Moreover, the shift by shiftable memory does not produce a lateral translation or shift of data outside of the contiguous subset of data involved in the shift, by definition herein. In general, the shift may move the data by a distance of one or more memory locations or memory addresses in the row. For example, the shift may move the data a single memory location to the right or left within the row. In another example, the shift may move the data two or more memory locations either right or left.

Herein, the direction ‘left’ is defined with respect to memory locations along a row within the shiftable memory as a direction toward locations having generally smaller addresses. The direction ‘right’ is defined as a direction along a row toward locations having generally larger addresses. Hence, a ‘left shift’ is defined as shifting the data to a second location in the row having a smaller address than an address of a first or starting location in the row, according to some examples. Conversely, a ‘right shift’ results in moving the data in the row from a first location having a smaller address to a second location with a larger address, according to some examples. However, while the shift direction is controllable or selectable according to some examples, the shift direction (e.g., right or left) may be completely arbitrary, as employed herein. Further, the specific use of ‘left shift’ and ‘right shift’ as well as the notion of smaller and large addresses herein is for discussion purposes and not by way of limitation.

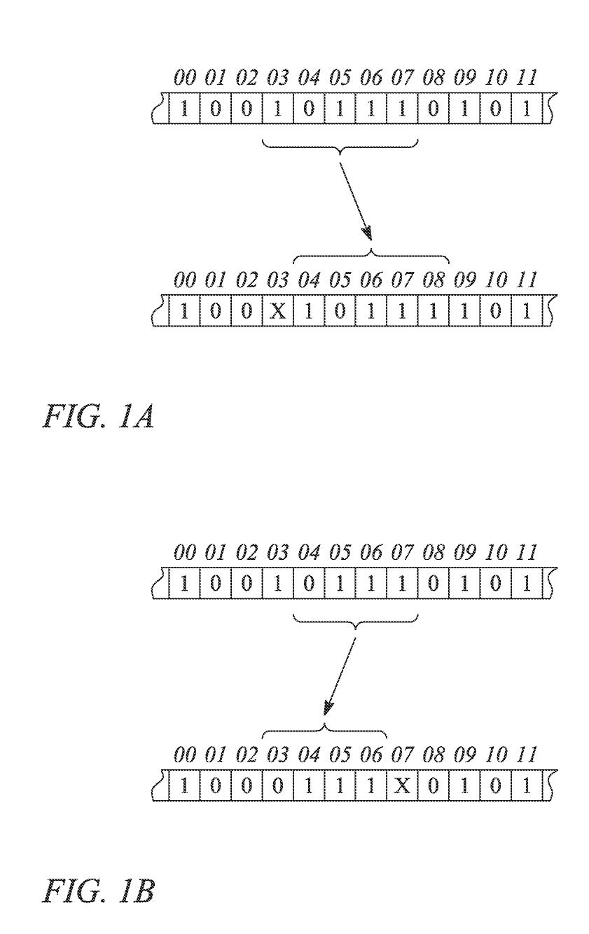

FIG. 1A illustrates an example of a right shift of a contiguous subset of data stored in a horizontal row within a shiftable memory, according to an example of the principles described herein. In particular, FIG. 1A illustrates a plurality of memory cells, each of which is capable of storing a data bit. For example, the data bits stored by the memory cell may comprise a binary bit (e.g., either a ‘1’ or ‘0’). Further as illustrated, each of the illustrated memory cells is identified by a decimal address ranging from 00 to 11. An upper portion of FIG. 1A illustrates the plurality of memory cells before the right shift while a lower portion illustrates the same plurality of memory cells after the right shift.

As illustrated in FIG. 1A, the example right shift within the shiftable memory comprises selecting a contiguous subset of stored data bits starting with a memory cell at address 03 and ending with a memory cell at address 07, for example. The selected contiguous subset contains the data bits {‘1’, ‘0’, ‘1’, ‘1’, ‘1’} in the illustrated example. The shiftable memory then right shifts the selected contiguous subset of data bits by moving the stored data bits to the right one address location, as illustrated in the lower portion of FIG. 1A. The right shift maintains an order of the data bits within the contiguous subset and deposits the contiguous subset in memory cells between address 04 and address 08. Right shifting the stored data overwrites the contents of a memory cell immediately to the right of an original location of the contiguous subset (i.e., at address 08) and replaces the contents of that memory cell with a last data bit (i.e., ‘1’) of the right shifted contiguous subset. Further, the memory cell at address 03 which originally held the first data bit of the contiguous subset is rendered indeterminate as indicated by the ‘X’. According to various examples, the memory cell at address 03 may retain a copy of the data bit (e.g., ‘1’) that was present before the right shift or may be cleared (e.g., set to ‘0’) as a result of the right shift. In some examples, the memory cell at address 03 may be available for insertion of a data bit from an external source, for example.

FIG. 1B illustrates an example of a left shift of a contiguous subset of data stored in a row within a shiftable memory, according to an example of the principles described herein. In particular, FIG. 1B illustrates a plurality of memory cells each of which stores a data bit (e.g., ‘1’, ‘0’, ‘0’, ‘1’, ‘0’, etc.). Further as illustrated, each of the illustrated memory cells is identified by an address ranging from 00 to 11. An upper portion of FIG. 1B illustrates the plurality of memory cells before the left shift while a lower portion illustrates the same plurality of memory cells after the left shift.

As illustrated in FIG. 1B, the left shift in shiftable memory comprises selecting a contiguous subset of stored data bits starting with a memory cell at address 04 and ending with a memory cell at address 07, for example. The shiftable memory then left shifts the selected contiguous subset by moving the data bits in the selected contiguous subset to the left, as illustrated in the lower portion of FIG. 1B. The left shift maintains an order of the words within the contiguous subset and deposits the contiguous subset in memory cells between address 03 and address 06. Left shifting the stored data bits overwrites the contents of a memory cell immediately to the left of an original location of the contiguous subset (i.e., at address 03) replacing the contents of that memory cell with a first data bit (i.e., ‘0’) of the left shifted contiguous subset. Further, the memory cell at address 07 which originally held the last data bit of the contiguous subset is rendered indeterminate, as indicated by the ‘X’. According to some examples, the memory cell at address 07 may retain a copy of the data bit (e.g., ‘1’) that was present before the right shift or may be cleared (e.g., set to ‘0’) after the left shift. In some examples, the memory cell at address 07 may be available for insertion of data from an external source, for example.

According to various examples, the shiftable memory may be a portion of a main memory of a general-purpose computer system. The shiftable memory may represent a subset of the memory that makes up the main memory, for example. Furthermore according to various examples, the shiftable memory is distinct from memory cells, cache and other relatively small memory structures often found integrated together with other components (e.g., an arithmetic logic unit, con(roller, etc.) in a microprocessor, for example. In particular, shiftable memory by definition herein, is part of the main memory and as such, is separate from a processor of a general-purpose computer system or related processing system, according to various examples. In addition, shiftable memory typically contains an order of magnitude or more memory storage than is present or can be present in the processor, according to some examples. For example, shiftable memory may include many megabytes or even gigabytes of memory storage whereas processor memory storage typically may be limited to less than a few tens of bytes (e.g., processor registers) to a few megabytes (e.g., L1 cache, L2 cache etc.). According to some examples, the shiftable memory may be a specialized partition of the main memory or a subsystem thereof.

Further, as used herein, the article ‘a’ is intended to have its ordinary meaning in the patent arts, namely ‘one or more’. For example, ‘a memory cell’ means one or more memory cells and as such, ‘the memory cell’ means ‘the memory cell(s)’ herein. Also, any reference herein to ‘top’, ‘bottom’, ‘upper’, ‘lower’, ‘up’, ‘down’, ‘front’, back’, ‘left’ or ‘right’ is not intended to be a limitation herein. Herein, the term ‘about’ when applied to a value generally means within the tolerance range of the equipment used to produce the value, or in some examples, means plus or minus 10%, or plus or minus 5%, or plus or minus 1%, unless otherwise expressly specified. Moreover, examples herein are intended to be illustrative only and are presented for discussion purposes and not by way of limitation.

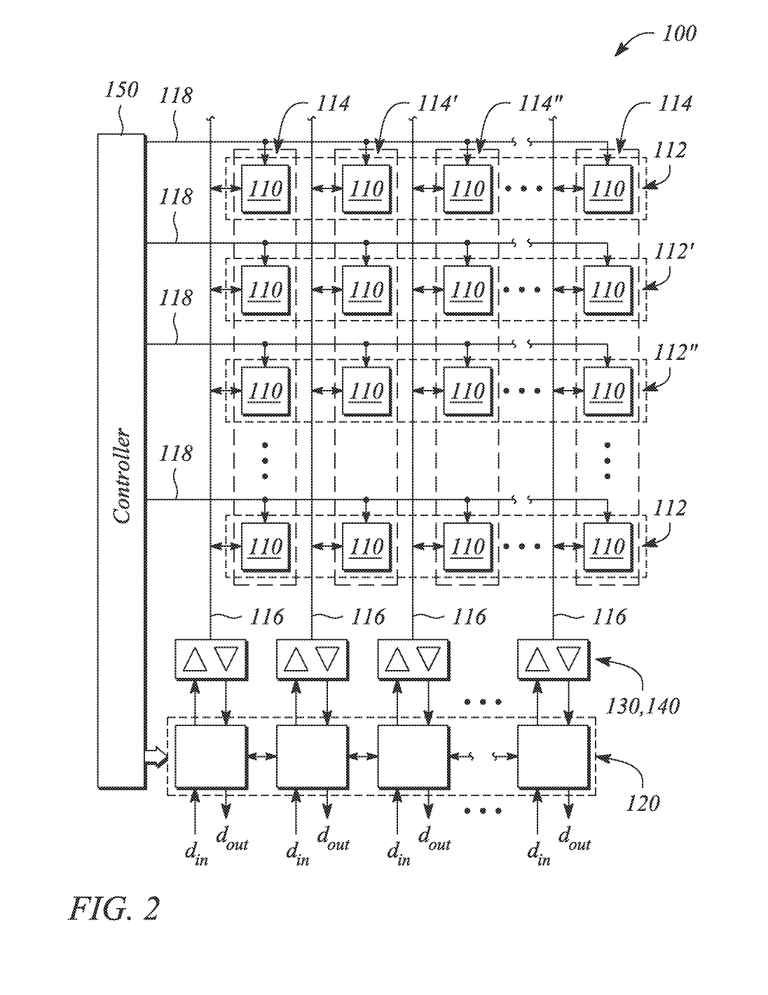

FIG. 2 illustrates a block diagram of a shiftable memory 100 that employs row shifting, according to an example in accordance with the principles described herein. The row shifting of the shiftable memory 100 moves or shifts data along a row of the shiftable memory 100, according to various examples. In some examples, the row shifting shifts all of the data in the row. In other examples, the row shifting shifts only a portion of the data in the row. Further, the data shifted by the row shifting is a contiguous subset of the data in the shiftable memory 100. In particular, the row shifting shifts only the data of the contiguous subset while data outside of the contiguous subset is not shifted, according various examples.

For example, when the entire row is shifted by row shifting within the shiftable memory 100, the contiguous subset comprises the entire row being shifted and only data within that row is shifted. However, when row shifting shifts only a portion of the data in a row, contiguous subset may comprise the shifted portion only while a remaining portion of the data in the row (i.e., albeit, outside of the contiguous subset) is not shifted, for example. In yet other examples, the contiguous subset may span more than a single row.

According to some examples, the shiftable memory 100 comprises an array of memory cells 110. In particular, the memory cells 110 of the array are arranged in a plurality of rows 112, according to some examples. The rows 112 of the plurality may be adjacent and substantially parallel to one another to form a 2-D array, as illustrated for example. In addition, the memory cells 110 of the array are further arranged in a plurality of columns 114, according to some examples. For example, the columns 114 may be adjacent and substantially parallel to one another. The rows 112 and the columns 114 generally intersect one another, according to various examples. For example, the rows 112 may run horizontally and the columns 114 may run vertically, as illustrated in FIG. 2. Further, a specific memory cell 110 is generally located in and thus is a member of bath a particular row 112 and a particular column 114 of the shiftable memory 100, according to various examples. Moreover, individual memory cells 110 may be designated or addressed according to which row 112 and to which column 114 the memory cell 110 is located, according to various examples.

For example, as illustrated, a first memory cell 110 may be located in a first row 112′ and a first column 114′. A second memory cell 110 may be located in the first row 112′, but in a second column 114″, for example. In another example, a third memory cell 110 may be in the first column 114, but in a second row 112″ while a fourth memory cell 110 may be located in the second row 112″ as well as in the second column 114″. As illustrated, each memory cell 110 along a given row 112 is in a different one of the plurality of columns 114. Likewise, each memory cell along a particular column 114 is in a different row 112 of the plurality of rows 112.

According to various examples, each column 114 has an input port, connection or pathway (i.e., ‘input’) and an output port, connection or pathway (i.e., ‘output’). The output of a column 114 may be used to communicate or transfer data out of a memory cell 110 of the column 114. The data transferred out may be data stored by the memory cell 110, for example. The input of a column 114 may be used to transfer data into a memory cell 110 of the column 114. For example, the data transferred into the memory cell 110 may be received and stored by the memory cell 110. The received and store data may overwrite or otherwise replace data already stored by the memory cell 110, according to some examples. In some examples, the input and the output may be a common or shared connection or pathway. For example, all of the memory cells 110 of a column 114 may be connected to a bus, a line or a wire that serves as one or both of the input and the output of the column 114. In another example, an output of a column 114 are separate connections or pathways.

In particular, as illustrated in FIG. 2, the memory cells 110 of a column 114 are connected in common to a bit line 116 that serves as both of the input and the output for the column 114. The bit line 116 of the column 114 may be used to read data from (i.e., transfer data out of) and write data to (i.e., transfer data into) memory cells 110 of the column 114, for example. In some examples (not illustrated), the bit line 116 comprises a pair of bit lines. The pair of bit lines 116 may be a differential pair in which data on the bit line is represented by a difference (e.g., a voltage difference) between the bit lines 116 of the differential pair, for example. Moreover, while a pair of bit lines 116 may be employed in some examples, the pair may serve as both the input and the output of a column 114, according to some examples (e.g., see below regarding SRAM).

According to some examples, at a particular time, only a single memory cell 110 of a column 112 is actively connected to the bit line 116 of the column 114 while other memory cells 110 of the column 114 are substantially disconnected at the particular time. A transistor acting as a switch may provide connection and disconnection from the bit line 116, for example. When the memory cell 110 is accessed or activated, the transistor switch is turned on to connect the memory cell 110 to the bit line 116. Connection of the memory cell 110 to the bit line one of transfers data stored in the memory cell 110 to the bit line 116 (i.e., the stored data is ‘placed’ on the bit line 16) and transfers data from the bit line 116 into the memory cell 110 for storage therein.

Transferring data from the memory cell 110 to the bit line 116 is often referred to as ‘reading’ data or performing a ‘read operation’ herein while transferring data from the bit line 116 into the memory cell 110 for storage is often referred as ‘writing’ data or performing a ‘write operation’ herein. In some examples (not illustrated), a write enable control line is used to control whether data is transferred to the bit line 116 (read) or data on the bit line 116 is transferred into and stored by the memory cell 110 (written). The write enable may be functionality built into the memory cells 110 themselves (e.g., as illustrated) or may be a functionality provided by the column 114, according to various examples.

In some examples, the memory cells 110 of a row 112 are connected in common to a word line 118. In some examples, connection to a word line 118 substantially defines a row 112. As illustrated in FIG. 2, a particular word line 118 accesses all of the memory cells 110 of a particular row 118. Further, each row 112 has a separate word line 118 to allow individual rows 112 to be accessed without accessing other rows 112, for example. Asserting the word line 118 of a particular row 112 (e.g., setting a logic ‘high’) accesses or activates the memory cells 110 connected to that row 112. Accessing or activating the memory cells 110 of a row 112 may be used to either read data stored previously in the memory cells 110 of the row 112 or to write data to the memory cells 110 of the row 112, for example.

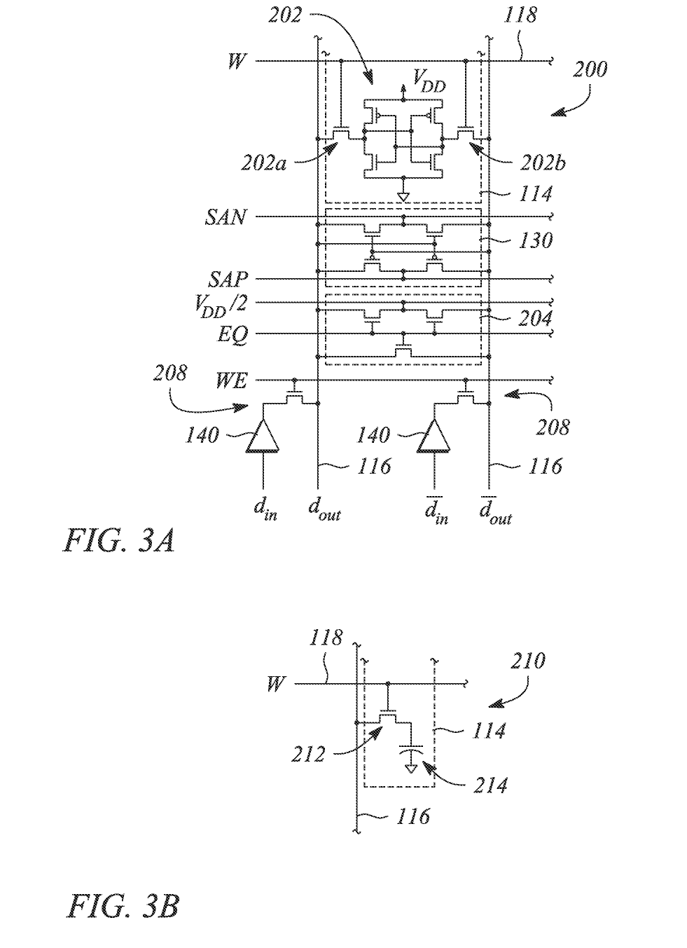

In some examples, the memory cell 110 comprises a static random access memory (SRAM) memory cell 200. FIG. 3A illustrates a schematic diagram of an example SRAM memory cell 200, according to an example in accordance with the principles described herein. The SRAM memory cell 200, illustrated in FIG. 3A, comprises six transistors 202. The SRAM memory cell 200 is configured to interface with a pair of differential bit lines 116 through a pair of transistors 202a, 202b. The differential bit lines 116 provide signals dₒᵤₜ and d̅ₒ̅ᵤ̅ₜ̅ as differential outputs or provide signals dᵢₙ and d̅ᵢ̅ₙ̅ as differential inputs to the SRAM memory cell 200, as illustrated. Gates of the pair of transistors 202a, 202b are connected to a word line 118 that may be driven by a word line signal W. The SRAM memory cell 200 is powered by a connection to a voltage source V_{DD}, as illustrated.

Asserting the word line signal W activates the pair of transistors 202a, 202b to connect the SRAM memory cell 200 to the bit lines 116. In particular, a word line signal W representing a logic ‘high’ on the word line 118 turns on or activates the pair of transistors 202a, 202b, according to sonic examples. The transistors 202a, 202b of the pair act as a pair of switches when activated to connect a remaining four transistors 202 of the SRAM memory cell 200 to the bit lines 116. The connection provided by the activated transistors 202a, 202b either allows data stored by the remaining four transistors 202 of the SRAM memory cell 200 to be transferred to the bit lines 116 or allows data (e.g., a voltage) on the bit lines 116 to be transferred to the remaining four transistors 202 of the SRAM memory cell 200 for storage by those transistors 202.

In some examples, the memory cell 110 comprises a dynamic random access memory (DRAM) memory cell 210. FIG. 3B illustrates a schematic diagram of an example DRAM memory cell 210, according to an example in accordance with the principles described herein. The DRAM memory cell 210 comprises a transistor 212 and a capacitor 214, as illustrated. A word line 118 is connected to a gate of the transistor 212 to activate the transistor when the word line 118 is asserted. In particular, the transistor 212 acts as a switch that connects the capacitor to a bit line 116 of a column 114 when a voltage is applied to the gate of the transistor 212 by asserting a word line signal W on the word line 118. The connection provided by the activated transistor 212 either allows data stored in the DRAM memory cell 210 (e.g., a voltage on the capacitor 214) to be transferred to the bit lines through the transistor 212 or allows data (e.g., a voltage)on the bit lines 116 to be transferred into the capacitor 214 of the DRAM memory cell 200 for storage therein.

Referring again to FIG. 2, the shiftable memory 100 further comprises shift logic 120. As illustrated, the shift logic 120 is connected between the columns 114. For example, the shift logic 120 is connected between a first column 114′ and a second column 114″ of the shiftable memory 100 (or e.g., between a column 114 and a column 114′, or between a column 114 and a column 114″). According to some examples, the shiftable memory 100 may comprise shift logic 120 that provides a plurality of connections between pairs or even sets of columns 114. For example, the shift logic 120 of FIG. 2 provides a connection between other pairs of columns 114 in addition to the aforementioned connection between the first column 114′ and the second column 114″ connection. However, since these other connections may function in a manner that is substantially similar to the first-to-second column connection, the discussion herein may be confined to the first-to-second column connection for simplicity and without loss of generality.

The shift logic 120 is configured to shift data from an output of the first column 114′ to an input of the second column 114″. For example, the shift logic 120 illustrated in FIG. 2 may be configured to shift data from a bit line 116 of the first column 114′ to a bit line 116 of a second column 114″. According to various examples, the shifted data is provided by a memory cell 110 of the first column 114′ in a selected row 112 of the plurality rows. The selected row 112 may be selected by asserting the word line 118 of that row 112, for example. The shifted data is received and stored by a memory cell 110 in the selected row 112 of the second column 114″, according to various examples.

In some examples, the shifted data may be latched or otherwise temporarily stored after being output by the memory cell 110 in the selected row 112 of the first column 114′ but prior to being provided by the shift logic 120 to the memory cell 110 in the selected row 112 of the second column 114″. Latching may be used to facilitate output and input of data over single bit line 116 (e.g., as illustrated in FIG. 2), for example. In particular, latching or equivalent temporary storage of the shifted data may avoid conflicts that can arise when trying to read and write data simultaneous using the bit line 116, according to various example. For example, when the same bit line 116 is used for both input and output from the memory cells 110 (e.g., as opposed to memory cells with separate input and output channels), the shifted data that is output by the first column memory cell 110 may be latched while the second column memory cell 110 (e.g., which also have provided shifted data to another memory cell) is made ready to receive and store the shifted data. Once the second column memory cell 110 is ready, the latched shifted data may be released and applied by the shift logic 120 to the second column memory cell 110, for example.

In some examples, the shift logic 120 is circuitry integral to the shiftable memory 100. For example, the shift logic 120 may be realized as a plurality of shift circuits that is built into a circuit of the shiftable memory 100. The shift circuits may be integral to an integrated circuit of the shiftable memory 100, for example. The shift circuits of the plurality may be connected between the first column 114′ bit line 116 and the second column 114″ bit line 116 to shift data output by the first column 114′ into the second column 114″. The shifted data may be stored in a memory cell 110 in a selected row 112 of the second column 114″, when shifted by the shift circuits, for example. In some examples, the shift logic 120 may comprise a latch to temporarily store the shifted data. In other examples, such as when wave-pipelining is employed to read and shift data, a dedicated latch on the bit line 116 may be omitted.

In some examples, the first column 114′ and the second column 114″ are adjacent to one another. For example, the first column 114′ and the second column 114″ are illustrated as adjacent to one another in FIG. 2. When the first and second columns 114′, 114″ are adjacent to one another, a shift of data by the shiftable memory 100 may result in movement of data in the selected row 112 by a single data bit per shift (e.g., a single memory location), for example. Shifts of more than one bit may be accomplished by repeating the shift, according to some examples. For example, a shift distance of one data word (e.g., 8 data bits) may be provided by eight, one-bit shifts.

In other examples, the first and second columns 114′, 114″ may be separated by one or more columns to produce a shift distance of more than one data bit. In particular, a number of columns between the first column 114′ and the second column 114″ may range from zero (e.g., for adjacent columns 114) to a number that is less than a total number of columns 114 of the shiftable memory 100, according to some examples. For example, a spacing between the first column 114′ and the second column 114″ may represent a shift distance of one data bit, or two, three, four, and so on data bits (not illustrated). Moreover, the shift distance may be selectable. Specifically, the shift logic 120 may provide selection of the number of columns 114 between the first column 114′ and the second column 114″. The selectable number of columns 114 may range from zero to a number less than a total number of columns 114 in the shiftable memory 100 (as mentioned above), for example.

In some examples, a direction of the shift may provide one or both of a left shift and a right shift. In particular, the shift logic 120 may be configured to shift the data in a direction along the selected row 112 that is one of toward the beginning (e.g., a left end) of the selected row and toward the terminal end (e.g., a right end) of the selected row 112. Arrows showing a direction of data flow in FIG. 2 illustrate the capability of the shift logic 120 to provide both of a left shift and a right shift. In some examples, the shift direction of the shift logic 120 is fixed as either a left shift or a right shift. In other examples, the shift direction may be selectable in situ. For example, the shift logic 120 may have a control input that, among other things, determines the shift direction (i.e., left shift or right shift).

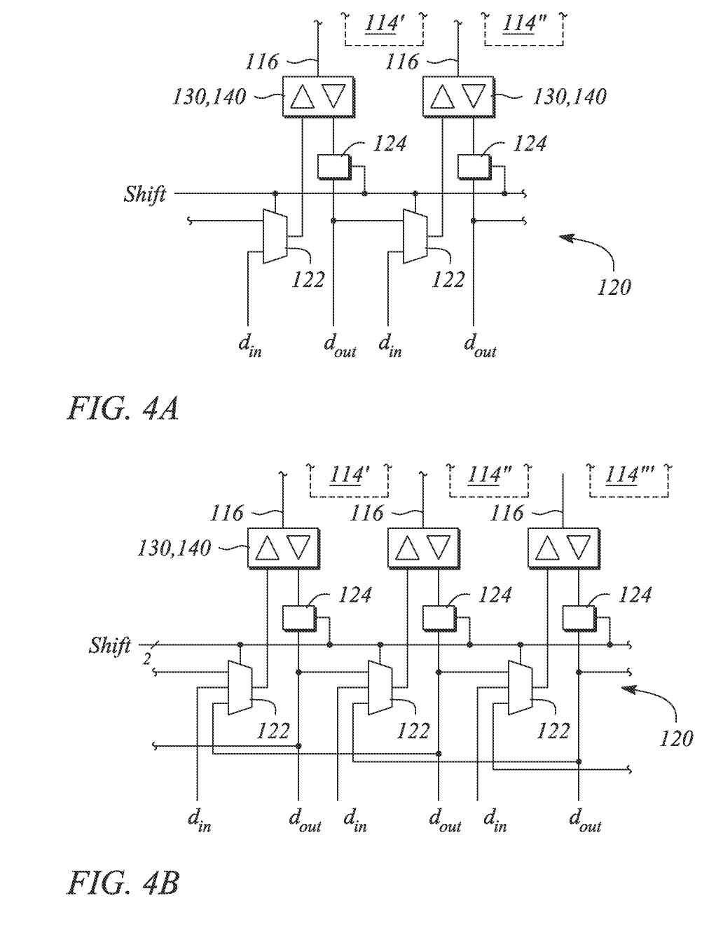

In some examples, the shift logic 120 comprises a multiplexer. The multiplexer may be connected to selectively route data from a first column 114 to a second column 114″, for example. FIG. 4A illustrates a schematic diagram of the shift logic 120 comprising a multiplexer 122, according to an example in accordance with the principles described herein. As illustrated, the multiplexer 122 has an input to receive data from an output or bit line 116 of the first column 114′. For example, the input of the multiplexer 122 may be connected to an output of a sense amplifier 130 (described below) of the first column 114′. Another input of the multiplexer 122 may be connected to an external data port of the shiftable memory 100 to receive data from an external source, for example. Further, as illustrated, an output of the multiplexer 122 is connected to direct data to the input or bit line 116 of the second column 114″. For example, the output of the multiplexer 122 may be connected to direct data to the bit line 116 of the second column 114″ via an input of a bit line driver 140 (described below) of the second column 114″.

As illustrated, the multiplexer 122 is configured to select between the externally sourced data dᵢₙ and data provided by the bit line 116 of the first column 114′. Further, the multiplexer 122 is configured to route the selected data to the input (e.g., to bit line 116) of the second column 114″ for storage in the memory cell 110 in the selected row 112 (not illustrated in FIG. 4A) of the second column 114″.

According to some examples, the first column 114′ is closer to the beginning of the selected row 112 than the second column 114″. In these examples, the shift implemented by the multiplexer 122 constitutes a right shift. In other examples, the first column 114′ is closer to the terminal end (e.g., right end) of the selected row than the second column 114″ such that the shift implemented by the multiplexer 122 constitutes a left shift. Control of the multiplexer 122 (i.e., which input is selected) is provided by a Shift signal, as illustrated in FIG. 4A. Data output by the first and second columns 114′, 114″ also may be provided at an output dₒᵤₜ for external use, for example.

FIG. 4B illustrates a schematic diagram of the shift logic 120 comprising a multiplexer 122, according to another example in accordance with the principles described herein. In particular, as illustrated in FIG. 4B, the multiplexer 122 has three inputs. A first input is connected to route data from the bit line 116 of the first column 114′, as described above. Likewise, a second input is connected to an external data port (e.g., dᵢₙ) of the shiftable memory 100, as described above. A third input of the multiplexer 122, is connected to receive data from a bit line of a third column 114′″ on a side of the second column 114″ opposite that of the first column 114′, as illustrated in FIG. 4B. For example, the third input may be connected to an output of a sense amplifier 130 of the third column 114′″.

As illustrated, selection by the multiplexer 122 of the first input may provide a right shift of data (e.g., move the data to the right) while selection of the third input may yield a left shift of the data (e.g., move the data to the left) along the selected row 112 (no(illustrated), for example. The Shift signal may be provided by a pair of lines to allow for selecting between the three inputs, as illustrated in FIG. 4B.

In some examples, the shift logic further comprises a latch 124. As illustrated in FIGS. 4A and 4B, the latch 124 may be located along the bit line 116 before the multiplexer 122. The latch 124 may temporarily store data output on the bit line 116 during a read operation, according to some examples. When shifting, the latch 124 may pass the data on the bit line 116 to a multiplexer 122 of a next stage, according to some examples. The Shift signal may be used to control the latch 124 as illustrated, for example. . . .

Referring to again to FIG. 2, the shiftable memory 100 further comprises one or both of a sense amplifier 130 and a bit line driver 140. As illustrated, the sense amplifier 130 and the bit line driver 140 are located between the plurality of rows 112 of memory cells 110 and the shift logic 120. The sense amplifier 130 may serve as an output interface between memory cells 110 of a column 114 and other components (e.g., the shift logic 120) connected to the column 114, for example. The bit line driver 140 may serve as an input interface between other components (e.g., the shift logic 120) and memory cells 110 of the column 114, for example.

According to various examples, the sense amplifier 130 amplifies a signal produced by the memory cell 110 of the selected row. For example, the sense amplifier 130 may amplify a voltage produced by the memory cell 110 when activated and provide the amplified voltage as an output of a column 114. The voltage may be amplified to a voltage level compatible with one or more of the shift logic 120, other components that interface with the shiftable memory 100, and other circuitry of the shiftable memory 100 itself, for example.

In some examples (e.g., DRAM), the sense amplifier 130 may also latch the amplified signal as a logic level (e.g., a logic ‘0’ or ‘1’). For example, the amplified signal of a DRAM memory cell may be latched to provide a stable output from the column 114 even as a voltage of the DRAM memory cell (e.g., a voltage on a capacitor) decays with time. The latched output provided by the sense amplifier 130 may also act to hold the shifted data from the first column 114′ until the data can be written to the second column 114″, for example. According to some examples, a tri-state buffer (not illustrated) or a substantially equivalent device may be employed on an output of the sense amplifier 130 to isolate the sense amplifier 130 from downstream components (e.g., a bit line driver). The tri-state buffer may be controlled by the Shift signal acting as an enable signal, for example.

According to various examples, the bit line driver 140 drives obit line 116 of a column 114 to provide sufficient input signal level to the memory cells 110 of the column. For example, the bit line driver 140 may provide a voltage to the bit line 116 that is sufficient to change a state of the memory cell 110 of the selected row 112 when data is to be stored by the memory cell 110. In some examples, the shift logic 120 comprises a multiplexer 122 (e.g., see FIG. 4A, 4B) connected to selectively route data produced at an output of the sense amplifier 130 of the bit line 116 of the first column 114′ to an input of the bit line driver 140 of the bit line 116 of the second column 114″. The multiplexer 122 may be configured to selectively route data when data is to be shifted, for example.

Referring to FIG. 3A, each column 114 containing a plurality of SRAM memory cells 200 may include a sense amplifier 130 and a voltage equalizer circuit 204. In some examples, the voltage equalizer circuit 204 may be included as part of the sense amplifier 130. The sense amplifier 130, illustrated in FIG. 3A may be driven by a sense amplifier driver (not illustrated) that provides drive voltages SAN and SAP, for example. The voltage equalizer circuit 204 is connected to and driven by a signal EQ and is powered by a voltage V_{DD}/2, as illustrated. Further still, as illustrated, each column 114 may comprise a pair of bit line drivers 140. The bit line drivers 110 may be connected to the bit lines 116 through a pair of transistors 208. The transistor 208 may be activated by a write enable (WE) signal, for example. The bit line drivers 140 may be configured to drive the bit lines 116 with the differential pair of input signals dᵢₙ and d̅ᵢ̅ₙ̅, for example.

Referring yet again to FIG. 2, the shiftable memory 100 is provided in a system that further comprises a controller 150, according to some examples. The controller 150 one or both of selects rows using word lines 118 associated with the rows 112 and controls the shift logic 120 to facilitate shifting, according to various examples. For example, the controller 150 may comprise a decoder that receives an address of the row 112 that is to be selected and shifted. The row address may be received from a system (e.g., a processor) external to the shiftable memory 100, for example. The controller 150 may further control the shift logic 120, according to some examples. For example, the controller 150 may provide the Shift signal (illustrated in FIGS. 4A and 4B). The controller 150 may further comprise another decoder that selects portions of the shift logic 120 to affect shifting of only a portion of the data in the selected row 112, for example. The controller 150 may further be configured to control one or both of a shift direction (e.g., left shift vs. right shift), a shift distance and whether or not a shift is to take place, according to various examples.

According to various examples, the shiftable memory 100 may be configured to shift data according to data word-sized shift distances. For example, the shiftable memory 100 may be configured to shift data according to a data word size that is one or more of 8-bit, 16-bit, 32-bit, 64-bit, and so on. A data word size may be defined by a system that employs the shiftable memory 100, for example. According to some examples, data words are stored sequentially along rows 112 of the shiftable memory 100. In these examples, a data word-sized shift may be accomplished by shift logic that shifts data bits of the row 112 a distance that equals the data word size, for example.

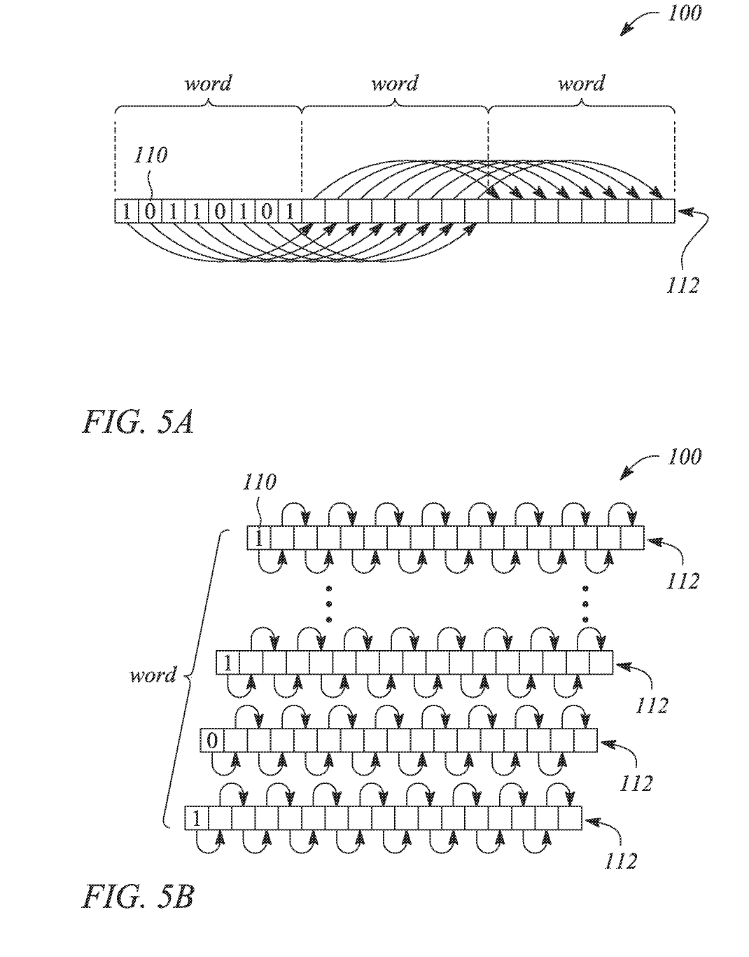

FIG. 5A illustrates a schematic block diagram of an example of word-sized shifting in the shiftable memory 100, according to an example in accordance with the principles described herein. As illustrated, data bits in a row 112 of memory cells 110 are shifted by eight bits (i.e., eight contiguous memory locations) corresponding to an 8-bit data word (e.g., ‘10110101’) by the shift logic during a shift. For example, a data bit in a first memory location of the row 112 may be shifted by the shift logic 120 to an eighth location, a data bit in a second memory location may be shifted by the shift logic 120 to a ninth memory location, and so on, for the contiguous set of data bits. Shift logic 120 that connects a first column 114′ with a second column 114″ that is displaced by eight columns 114 from the first column 114′ may be used to accomplish the shift illustrated in FIG. 5A, for example. The shift is illustrated using curved arrows in FIG. 5A.

FIG. 5B illustrates a schematic block diagram of an example of word-sized shifting in the shiftable memory 100, according to another example in accordance with the principles described herein. In particular as illustrated in FIG. 5B, a data word is distributed across a plurality of rows 112. Further, when data is shifted by the shiftable memory 100, all of the rows 112 of the plurality illustrated in FIG. 5B are shifted in a substantially simultaneous manner. The plurality of rows 112 may be in separate, substantially parallel arrays (e.g., a 3-D array) of shiftable memory 100, for example. The data bits of the data word are shifted by a single memory location (e.g., by one memory cell 110) along each of the rows 112, as illustrated by curved arrows in FIG. 5B. However, the shift results in moving the data word by a full word-sized distance in the memory since the data word is distributed across multiple shifted rows 112 that are shifted substantially simultaneously. Shift logic 120 that connects a first column 114′ with an adjacent second column 114″ may be used to accomplish the shift illustrated in FIG. 5B, for example. In some examples, data may be stored as interleaved data blocks with differing granularity to provide control over shifting. Further, as illustrated in FIG. 5B, the contiguous subset of data comprises a plurality of contiguous subsets, one contiguous subset for each of the rows 112 of the plurality.

FIG. 5C illustrates a schematic block diagram of an example of shifting in the shiftable memory 100 that employs remapping to dynamically control a shift distance, according to another example in accordance with the principles described herein. In particular, remapping may be used to dynamically change a shift distance in a shiftable memory 100 having a fixed shift distance, according to some examples. For example, a shiftable memory 100 may provide a fixed physical shift distance of one memory location, as illustrated by curved arrows in FIG. 5C. If a set of sequential data is stored in a row 112 of a single first array, the shift distance provided by the shiftable memory 100 is equal to fixed physical shift distance (e.g., a distance of one). However, if the data is remapped and stored in a pair of arrays, shifting by a fixed physical distance of one memory location may provide a ‘logical’ shift distance of two, for example.

As illustrated in FIG. 5C, if a set of sequential data (e.g., numbered ‘1’ ‘2’, ‘3’ and so on) is remapped so that odd numbered data bits are located in a row 112 of a first array 502 and even numbered bits are located in a corresponding row 112 of a second array 504, then a logical shift distance of two memory locations is provided by a physical shift distance of one memory cell. Remapping may be employed to provide logical shift distances by adding additional arrays (not illustrated) and distributing the set of sequential data across the added additional arrays. Moreover, remapping may be used dynamically to change a shift distance in a deployed shiftable memory 100 having a fixed physical shift distance. Selectable remapping may be provided by multiplexers on address lines (not illustrated) that control the arrays, for example.

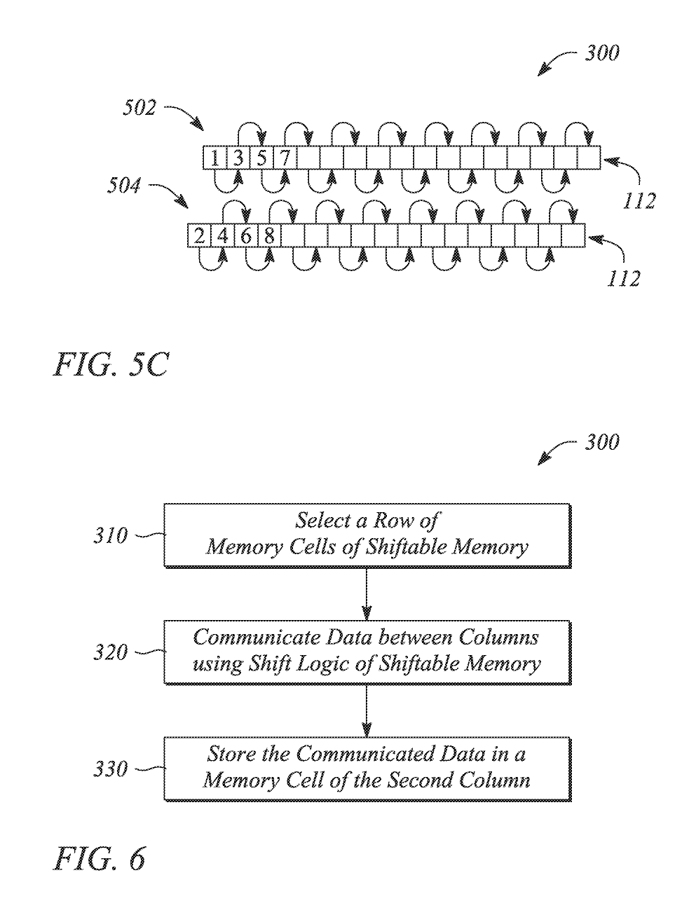

FIG. 6 illustrates a flow chart of a method 300 of shifting data in a shiftable memory, according to an example in accordance with the principles described herein. As illustrated, the method 300 of shifting data comprises selecting 310 a row of memory cells of the shiftable memory. According to various examples, the memory cells of the shiftable memory are arranged as a plurality of rows and a plurality of columns. According to some examples, the memory cells of the shiftable memory as well as the shiftable memory itself are substantially similar to respectively the memory cells 110 and the shiftable memory 100, described above.

The method 300 of shifting data further comprises communicating 320 data between columns using shift logic of the shiftable memory from a first column to a second column of the plurality. In some examples, the shift logic connects between and shift data from a bit line of the first column to a bit line of the second column. The communicated data may be data provided by a memory cell of the first column in the selected row, for example. According to some examples, the shift logic may be substantially similar to the shift logic 120 described above with respect to the shiftable memory 100.

The method 300 of shifting data further comprises storing 330 the communicated data in a memory cell of a second column in the selected row. Storing 330 the communicated data may be accomplished by the memory cell in a manner that is consistent with an operational characteristic of the memory cell, for example. The communicated data is shifted along the selected row from the first column memory cell to the second column memory cell, according to various examples.

In some examples (not illustrated), communicating 320 data comprises amplifying a signal from the memory cell of the first column. Amplifying may be accomplished using a sense amplifier to produce the data at an output of the sense amplifier, for example. According to some examples, the sense amplifier may be substantially similar to the sense amplifier 130 described above with respect to the shiftable memory 100.

In some examples, communicating 320 data further comprises selectively transferring the data from the output of the sense amplifier to an input of a bit line driver of the second column. Selectively transferring the data may be performed by shift logic of the shiftable memory when the data is shifted, for example. In some examples, communicating 320 data further comprises driving the bit line of the second column using the bit line driver to produce a signal that facilitates storing the data in the memory cell of the second column in the selected row.

Thus, there have been described examples of a shiftable memory, shiftable memory system and a method of shifting data in a shiftable memory that employ row shilling. It should be understood that the above-described examples are merely illustrative of some of the many specific examples that represent the principles described herein. Clearly, those skilled in the art can readily devise numerous other arrangements without departing from the scope as defined by the following claims.

What is claimed is:

1. A shiftable memory comprising:
memory cells arranged as a plurality of rows and a plurality of columns; and
shift logic to shift data from an output of a first column to an input of a second column, the shifted data being provided by a memory cell of the first column in a selected row and the shifted data being received and stored by a memory cell in the selected row of the second column,
wherein the shift logic is to facilitate shifting data along the selected row.

2. The shiftable memory of claim 1, wherein the first column and the second column are adjacent to one another and all of the data within the selected row is shifted by the shift logic.

3. The shiftable memory of claim 1, wherein a number of columns between the first column and the second column is selectable between zero and a number that is less than a total number of columns of the shiftable memory.

4. The shiftable memory of claim 1, wherein the shift logic is to shift the data in a direction along the selected row that is one of toward a beginning of the selected row and toward an end of the selected row.

5. The shiftable memory of claim 1, wherein the shift logic comprises a multiplexer having an input connected to the output of the first column and having a multiplexer output connected to the input of the second column, the multiplexer to select between data from another input of the multiplexer and data on the first column output, and further the multiplexer to route the selected data to the input of the second column for storage in the memory cell in the selected row of the second column.

6. The shiftable memory of claim 1, further comprising one or both of a sense amplifier and an bit line driver on bit lines of the first column and the second column, the sense amplifier and the bit line driver being between the plurality of rows of memory cells and the shift logic.

7. The shiftable memory of claim 6, wherein the shift logic comprises a multiplexer connected to selectively route data produced at an output of the sense amplifier of the bit line of the first column to an input of the bit line driver of the bit line of the second column, the multiplexer to selectively route data when data is to be shifted.

8. The shiftable memory of claim 1, wherein the memory cell comprises one of a dynamic random access memory (DRAM) memory cell and a static random access memory (SRAM) memory cell, the output and the input of the columns comprising bit lines associated with either the DRAM memory cell or the SRAM memory cell.

9. The shiftable memory of claim 1, further comprising a controller one or both of to select the rows using word lines associated with the rows and to control the shift logic to facilitate shifting data.

10. A shiftable memory system comprising:
an array of memory cells arranged in rows and columns, memory cells of each row being connected in common to a word line of the row and memory cells of the columns being connected in common to a bit line of the column;
a plurality of shift circuits, a shift circuit of the plurality being connected between a first column bit line and a second column bit line to shift data output by the first column into the second column, the shifted data to be stored in a memory cell in unelected row of the second column; and
a controller to select the rows using the word lines and to control the shift logic circuit to facilitate shifting data.

11. The shiftable memory system of claim 10, further comprising one or both of a sense amplifier and a bit line driver between the array of memory cells and the shift circuits, the sense amplifier to produce the output data from a signal on the first bit line generated by a memory cell of the first column in the selected row and the bit line driver to provide the output data to the memory cell in the selected row of the second column.

12. The shiftable memory system of claim 10, wherein the memory cell comprises one of a dynamic random access memory (DRAM) memory cell and a static random access memory (SRAM) memory cell, the bit lines comprising pairs of bit lines associated with either the DRAM memory cell or the SRAM memory cell.

13. The shiftable memory system of claim 10, wherein the data comprises data words, the data words being stored one of sequentially along one or more of the rows of the plurality and distributed across a plurality of adjacent arrays in corresponding rows.

14. A method of shifting data in a shiftable memory, the method comprising:
selecting a row of memory cells of the shiftable memory, the memory cells of the shiftable memory being arranged as a plurality of rows and a plurality of columns;
communicating data between columns using shift logic of the shiftable memory, communicating data being from a first column to a second column, the data being provided by a memory cell of the first column in the selected row; and
storing the communicated data in a memory cell of a second column in the selected row,
wherein the communicated data is shifted along the selected row from the first column memory cell to the second column memory cell.

15. The method of shifting data in shiftable memory of claim 14, wherein communicating data between columns comprises:
amplifying a signal on a bit line from the memory cell of the first column using a sense amplifier to produce the data at an output of the sense amplifier;
selectively transferring the data from the output of the sense amplifier to an input of a bit line driver of the second column; and
driving the bit line of the second column using the bit line driver to produce a signal that facilitates storing the data in the memory cell of the second column in the selected row,
wherein selectively transferring the data is performed by shift logic of the shiftable memory when data is shifted.
